(19) United States
(12) Patent Application Publication
(10) Pub. No.: US 2026/0298350 A1
(43) Pub. Date: Oct. 1, 2026

(54) PENDULUM VALVE APPARATUS, SUBSTRATE PROCESSING APPARATUS INCLUDING THE SAME, AND METHOD OF OPERATING PENDULUM VALVE APPARATUS

(71) Applicant: Samsung Electronics Co., Ltd., Suwon-si (KR)

(72) Inventors: Seungjae KIM, Suwon-si (KR); Dongho SHIN, Suwon-si (KR); OH-HYUK KWON, Suwon-si (KR); HUN KIM, Suwon-si (KR)

(21) Appl. No.: 19/427,920

(22) Filed: Dec. 19, 2025

(30) Foreign Application Priority Data
Mar. 25, 2025 (KR) 10-2025-0038276

(51) Int. Cl. F16K 3/04; F16K 27/04; F16K 27/12

(52) U.S. Cl. CPC F16K 3/04; F16K 27/045; F16K 27/12

(57) ABSTRACT

A pendulum valve apparatus comprises a housing including a main frame, a cover frame, and a vent passage in the main frame, the vent passage configured to connect to an exhaust line, a pendulum provided in the housing, the pendulum configured to selectively sela the vent passage, and a slit valve between the main frame and the cover frame of the housing. The main frame encloses a first space in the main frame and the cover frame encloses a second space in the cover frame. The slit valve is configured to selectively open and close an aperture of the first space, the aperture of the first space being located between the first space and the second space.

### CROSS-REFERENCE TO RELATED APPLICATIONS

This U.S. non-provisional patent application claims priority under 35 U.S.C. § 119 to Korean Patent Application No. 10-2025-0038276, filed on Mar. 25, 2025, in the Korean Intellectual Property Office, the entire contents of which are hereby incorporated by reference.

### BACKGROUND

Embodiments of the inventive concept relate to a pendulum valve apparatus, an apparatus for processing a substrate including the same, and a pendulum valve apparatus processing method.

In order to apply a vacuum to a space requiring a vacuum in a semiconductor manufacturing apparatus, for example, a chemical vapor deposition apparatus using plasma, an etching apparatus, or the like, it is necessary to connect a vacuum pump to pump gas from the chamber. Opening/closing equipment is installed in an exhaust line connecting the chamber and the vacuum pump. The opening/closing equipment opens and closes the exhaust line and controls a pumping state from the vacuum pump.

In general, a valve is designed to regulate the flow rate of a fluid. Using the valve, flow can be allowed or completely blocked. In addition, certain types of valves provide the possibility to regulate the flow rate per unit time, i.e., providing the possibility of controlling the fluid flow.

A vacuum valve is a particular type of a valve. The vacuum valve is available in various designs for regulating a volume or mass flow and/or for hermetic closure of the flow path running through an opening formed in the valve housing. The vacuum valve is used in vacuum chamber systems of IC, semiconductor, and/or substrate production fields, which processes preferably have to be done in a protected atmosphere free of contaminant particles.

A pendulum valve for semiconductor equipment includes a housing provided in an exhaust line connecting a chamber and a vacuum pump, and a plate provided inside the housing to open and close the exhaust line. In the case of the plate, since it directly blocks the exhaust line through which the gas directly flows, the surface of the plate is easily contaminated and may need to be serviced regularly. Therefore, the housing of the pendulum valve should be separated and the plate should be cleaned to service the pendulum valve as part of regular maintenance.

### SUMMARY

An embodiment of inventive concept may provide a pendulum valve apparatus that may prevent contamination of a chamber and a substrate processing apparatus including the same.

An embodiment of inventive concept may provide a method of operating a pendulum valve apparatus which provides a simple process for disassembling and assembling the pendulum valve apparatus.

According to an aspect of an example embodiment, a pendulum valve apparatus may include: a housing including a main frame and a cover frame, and a vent passage in the main frame, the vent passage configured to connect to an exhaust line; a pendulum provided in the housing, the pendulum configured to selectively seal the vent passage; and a slit valve between the main frame and the cover frame of the housing. The main frame may enclose a first space in the main frame and the cover frame may enclose a second space in the cover frame. The slit valve may be configured to selectively open and close an aperture of the first space, the aperture of the first space being located between the first space and the second space.

According to an aspect of an example embodiment, a substrate processing apparatus may include: a chamber having a substrate processing space disposed therein; a pump configured to regulate a pressure inside the chamber; an exhaust line connecting the chamber and the pump; and a pendulum valve apparatus provided on the exhaust line. The pendulum valve apparatus may comprise: a housing enclosing a first space and a second space therein, and the exhaust line is connected to the first space; a pendulum connected to the housing; a pendulum drive connected to the pendulum in the second space of the housing and configured to provide a driving force to the pendulum to selectively move a portion of the pendulum between the first space and the second space; and a slit valve coupled to the housing and configured to selectively seal an aperture of the first space, the slit valve being disposed between the first space and the second space.

According to an aspect of an example embodiment, a method of operating a pendulum valve apparatus that comprises a housing connected to an exhaust line connecting a chamber with a vacuum pump, the housing including a main frame providing a first space connected to the exhaust line and a cover frame providing a second space connected to the first space, a pendulum provided in the second space of the cover frame, and a slit valve connected to the main frame and connecting the second space to the first space, may include: moving a portion of the pendulum through the slit valve from the first space into the second space; with the portion of the pendulum disposed in the second space, closing the slit valve to seal the first space from the second space; separating the cover frame and the pendulum from the main frame with the slit valve closed and sealing the first space; coupling the cover frame and the pendulum to the main frame with the slit valve closed and sealing the first space; opening the slit valve to open a passage between the first space and the second space; and moving a portion of the pendulum into the first space through the slit valve to seal the exhaust line.

### BRIEF DESCRIPTION OF THE DRAWINGS

The above and other aspects, features, and advantages of certain example embodiments of the present disclosure will be more apparent from the following description with the accompanying drawings.

FIG. 1 is a block diagram of a substrate processing apparatus according to embodiments of the inventive concept.

FIG. 2 is a cross-sectional view illustrating a substrate processing apparatus according to embodiments of the inventive concept.

FIGS. 3 and 4 are perspective views illustrating a pendulum valve apparatus according to embodiments of the inventive concept.

FIG. 5 is a plan view of FIG. 4.

FIG. 6 is a cross-sectional view of FIG. 4.

FIG. 7 is a perspective view illustrating a pendulum valve apparatus according to embodiments of the inventive concept.

FIG. 8 is a plan view of FIG. 7.

FIG. 9 is a cross-sectional view of FIG. 7.

FIG. 10 is a perspective view illustrating a pendulum valve apparatus according to embodiments of the inventive concept.

FIG. 11 is a plan view of FIG. 10.

FIG. 12 is a cross-sectional view of FIG. 10.

FIGS. 13 to 17 are perspective views illustrating a method of operating a pendulum valve apparatus according to embodiments of the inventive concept.

### DETAILED DESCRIPTION

Example embodiments of the inventive concepts will now be described more detail with reference to the accompanying drawings, in which example embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. As used herein, items described as being “fluidly connected” or in “fluid communication” are configured such that a liquid or gas can flow, or be passed, from one item to the other.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

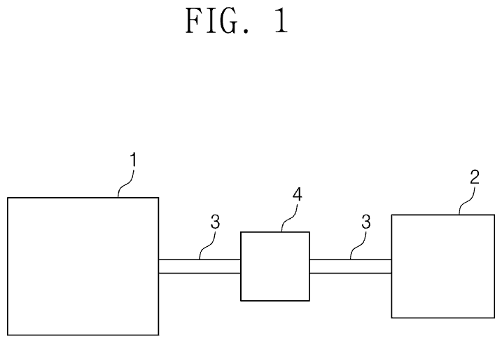

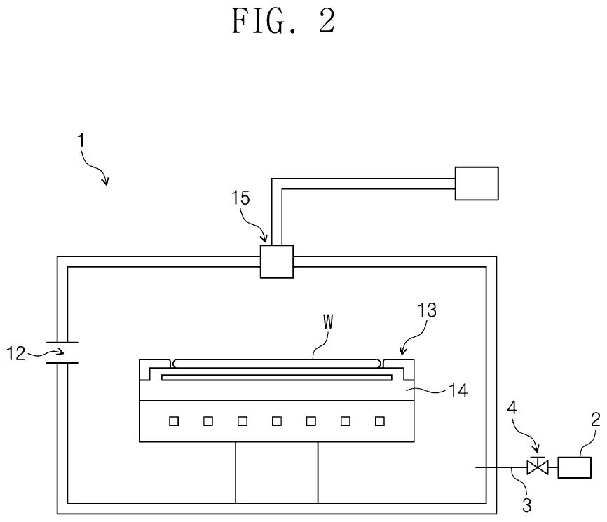

FIG. 1 is a block diagram of a substrate processing apparatus according to embodiments of the inventive concept. FIG. 2 is a cross-sectional view illustrating a substrate processing apparatus according to embodiments of the inventive concept.

Referring to FIG. 1, a substrate processing apparatus may include a process chamber 1 in which a semiconductor manufacturing process is performed, a vacuum pump 2 for forming a vacuum pressure, an exhaust line 3 connecting the process chamber 1 and the vacuum pump 2, and a pendulum valve apparatus 4 provided in the exhaust line 3 to regulate a degree of vacuum. Hereinafter, an example of a substrate processing apparatus according to the inventive concept will be described with reference to FIG. 2.

Referring to FIG. 2, the process chamber 1 may provide a processing space in which a substrate processing process is performed. The process chamber 1 may include a processing space therein and may have a closed shape. A slit valve 12 may be provided on one side wall of the process chamber 1. The slit valve 12 may be an entrance through which a substrate W to be processed is inserted into the process chamber 1 from outside of the process chamber 1.

A substrate support unit 13 may be provided in the process chamber 1. The substrate support unit 13 may include a chuck 14. The chuck 14 may be disposed on a bottom surface of the process chamber 1. The substrate W may be loaded on a top surface of the chuck 14. A substrate processing process may be performed on the loaded substrate W. According to embodiments of the invention, the chuck 14 may be an electrostatic chuck that supports the substrate W using electrostatic force. Alternatively, the substrate W on the top surface of the chuck 14 may be supported in various manners such as vacuum or mechanical clamping. The chuck 14 may include a body portion defining a space in which the substrate W is disposed, a DC electrode and a heater in the body portion, and dimples supporting the substrate W.

A gas supply unit 15 may be provided above the substrate support unit 13 in the process chamber 1. The gas supply unit 15 may supply a process gas into the process chamber 1. According to embodiments of the invention, the gas supply unit 15 may include a gas storage unit in which the process gas is stored, a gas supply port coupled with the process chamber 1, and a gas supply line connected between the gas storage unit and the gas supply port.

The vacuum pump 2 may be provided outside the process chamber 1. The vacuum pump 2 may be connected to the process chamber 1 using the exhaust line 3. The exhaust line 3 may pass through the housing of the process chamber 1 and may be connected with an interior of the process chamber 1. The vacuum pump 2 may regulate a pressure inside the process chamber 1 through the exhaust line 3. Between the process chamber 1 and the vacuum pump 2, the pendulum valve apparatus 4 may be coupled to the exhaust line 3. The pendulum valve apparatus 4 may be connected (or installed) in a middle of the exhaust line 3, and may open and close the exhaust line 3.

Hereinafter, the pendulum valve apparatus 4 will be described in more detail.

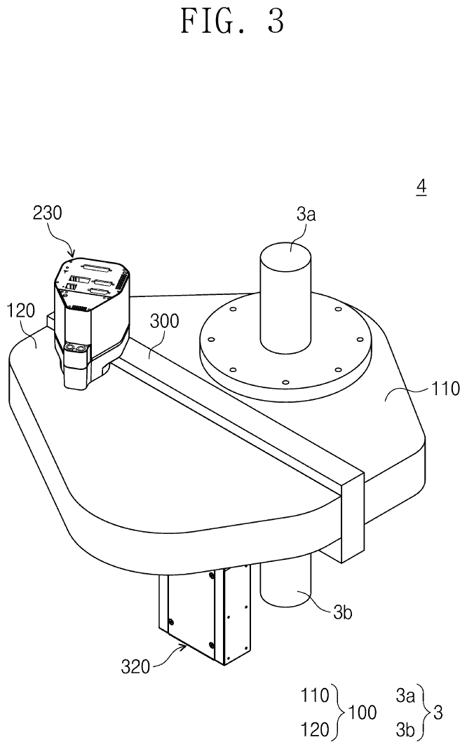

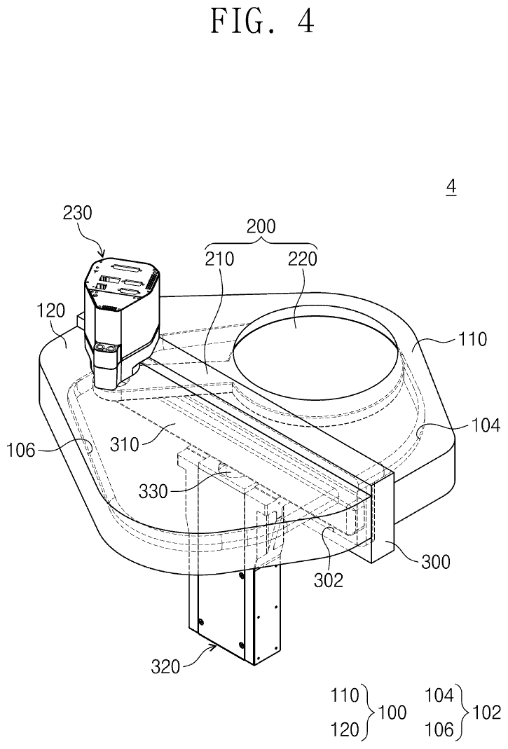

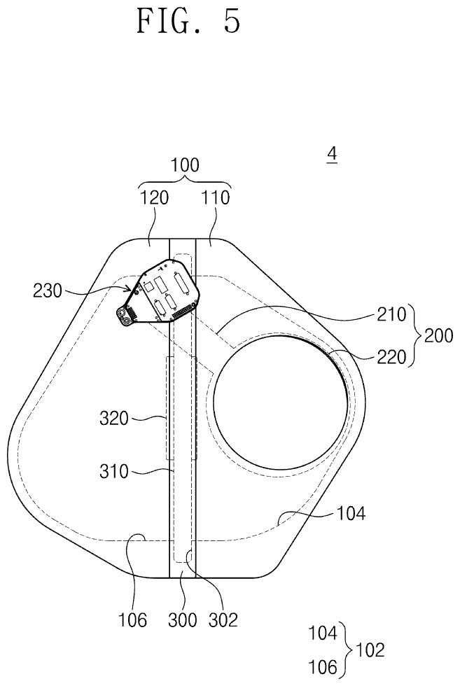

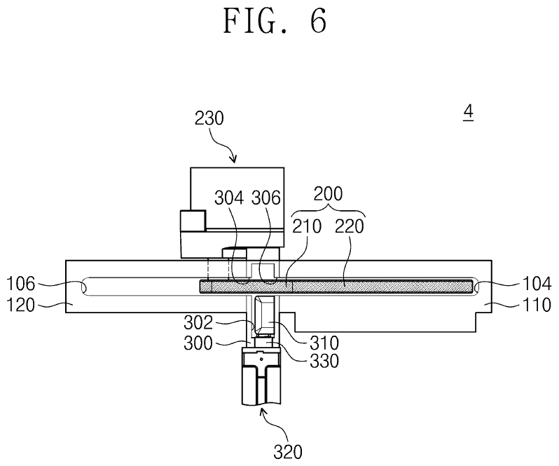

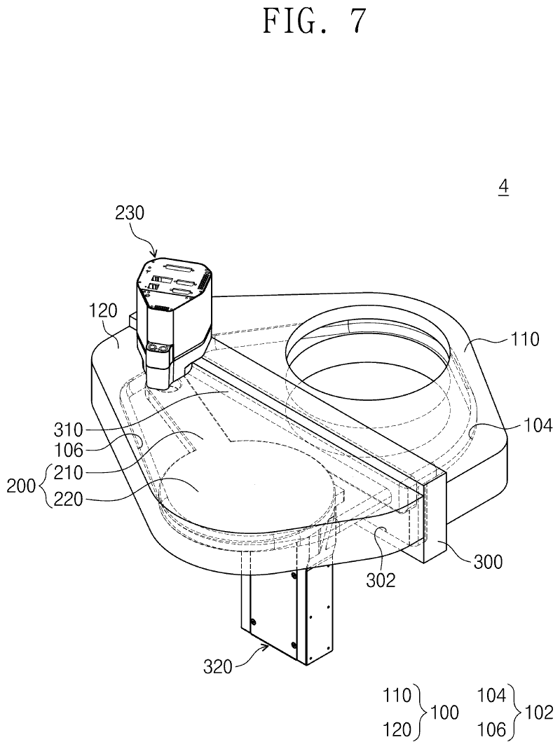

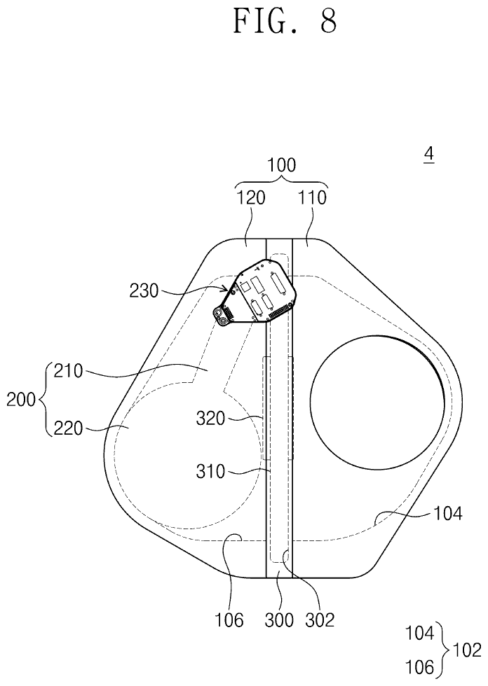

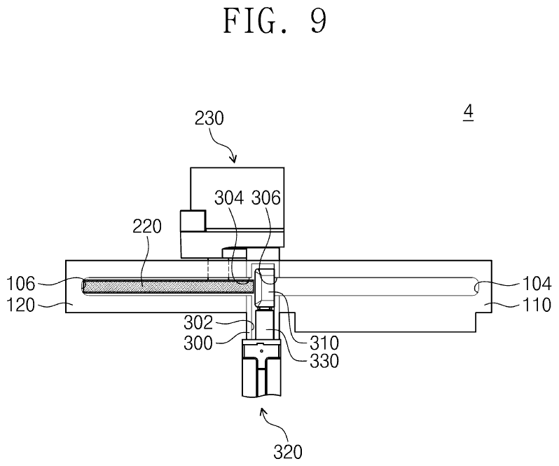

FIG. 3 is a perspective view illustrating a pendulum valve apparatus according to embodiments of the inventive concept. FIG. 4 is a perspective view illustrating a pendulum valve apparatus according to embodiments of the inventive concept and shows the inside of the pendulum valve apparatus. FIG. 5 is a plan view of FIG. 4. FIG. 6 is a cross-sectional view of FIG. 4. FIG. 7 is a perspective view illustrating a pendulum valve apparatus according to embodiments of the inventive concept and shows the inside of the pendulum valve apparatus. FIG. 8 is a plan view of FIG. 7. FIG. 9 is a cross-sectional view of FIG. 7.

Referring to FIGS. 3 to 6, the pendulum valve apparatus 4 may include a housing 100 in which a first internal space 102 is provided therein, a pendulum 200 provided in the first internal space 102 of the housing 100, and a slit valve 300 crossing the first internal space 102 of the housing 100 (e.g., the slit valve may divide the first internal space 102). The pendulum 200 may be rotated to open and close a gas flow passage of the exhaust line 3.

The housing 100 may be installed to the exhaust line 3a, 3b leading from the process chamber 1 (see FIGS. 1 and 2) to the vacuum pump 2 (see FIGS. 1 and 2). The first internal space 102 of the housing 100 may be connected with the exhaust line 3a, 3b.

The housing 100 may include a main frame 110 to which the exhaust line 3a, 3b is connected, and a cover frame 120 connected to the main frame 110. The cover frame 120 may be detachably coupled to the main frame 110. The main frame 110 and the cover frame 120 may surround the first internal space 102 of the housing 100. The exhaust line 3a, 3b may be connected to the main frame 110. The main frame 110, the cover frame 120, and the exhaust line 3a, 3b may be sealed from an external space. For convenience of description, a portion of the first internal space 102 located in the main frame 110 of the housing 100 is referred to as a first space 104, and a portion of the first internal space 102 located in the cover frame 120 of the housing 100 is referred to as a second space 106. For example, the main frame 110 may enclose the first space 104 and the cover frame may enclose the second space 106.

The pendulum 200 may be provided in the first internal space 102 of the housing 100. The pendulum 200 may be rotatably coupled to the cover frame 120 and may move (e.g., swing) such that a portion of the pendulum may move between the first space 104 and the second space 106. The pendulum 200 may comprise a pendulum shaft 210 and a plate 220. A first end of the pendulum shaft 210 may be coupled to the cover frame 120. The plate 220 may be connected to a second end of the pendulum shaft 210. The pendulum 200 may be rotated about the first end of the pendulum shaft 210 which is connected to the cover frame 120. The plate 220 may open and close the gas flow passage (or gas flow path) of the exhaust line 3a, 3b according to the rotation of the pendulum 200. For example, as shown in FIGS. 4 to 6, the pendulum 200 may rotate about the first end of the pendulum shaft 210 to a first configuration such that the plate 220 is located in the first space 104 of the main frame 110. In the first configuration the plate 220 may block or seal the exhaust line 3a, 3b connected to the first space 104 of the main frame 110 (e.g., the plate 220 may obstruct a flow path through the housing 100 the from the first exhaust line 3a to the second exhaust line 3b). For example, as shown in FIGS. 7 to 9, the pendulum 200 may rotate about the first end of the pendulum shaft 210 to a second configuration such that the plate 220 is located in the second space 106 of the cover frame 120. The second space 106 may have a larger area than that of the pendulum 200 in a vertical view (e.g., a plan view taken perpendicular to a rotation axis of the pendulum). In the second configuration the plate 220 may open the exhaust line 3a, 3b connected to the first space 104 of the cover frame 120 (e.g., the plate 220 may no longer obstruct the flow path through the housing 100 from the first exhaust line 3a to the second exhaust line 3b). In another example, the pendulum 200 may rotate about the first end of the pendulum shaft 210 to a third configuration such that the plate 220 is partially located in the first space 104 of the main frame 110. In the third configuration the plate 220 may partially block the exhaust line 3a, 3b connected to the first space 104 of the main frame 110 (e.g., the plate 220 may restrict the flow path through the housing 100 from the first exhaust line 3a to the second exhaust line 3b). Opening/closing state of the pendulum valve apparatus 4 may be adjusted by a rotation angle of the pendulum 200. Although the pendulum 200 is shown in FIGS. 3-9 as having the pendulum shaft 210 connected to the plate 220 such that the plate is aligned along an axis of the pendulum shaft 210, the present invention is not limited thereto. The pendulum 200 may be provided as a single plate structure, such as a single plate having a planar shape in the form of water droplet (e.g., a teardrop), or may be provided in various structures capable of opening and closing the connected exhaust line 3a, 3b.

The pendulum valve apparatus 4 may further comprise a pendulum drive 230 for adjusting rotational movement of the pendulum 200. The pendulum drive 230 may be coupled to the cover frame 120 of the housing 100. The pendulum drive 230 may be located outside the cover frame 120. The pendulum drive 230 may have a drive shaft passing through the cover frame 120, and the drive shaft may be connected to the first end of the pendulum shaft 210 of the pendulum 200. The pendulum drive 230 may rotate the pendulum 200 about the drive shaft, and may move the plate 220 of the pendulum between the first space 104 or the second space 106. The pendulum drive 230 may include, for example, a drive motor (e.g., a step motor). The pendulum drive 230 may be controlled by an external electronic device.

The slit valve 300 may be provided with the housing 100. The slit valve 300 may be disposed to divide the first internal space 102 of the housing 100. The slit valve 300 may be located between the first space 104 and the second space 106 of the housing 100. The slit valve 300 may be coupled to the main frame 110. The main frame 110 may have an aperture or opening which the slit valve 300 may cover. The aperture or opening may provide access to the first space through the main frame 110. The cover frame 120 may be coupled to the slit valve 300. The cover frame 120 may be detachably coupled to the slit valve 300 so as to be detachable from the main frame 110. For example, the cover frame 120 may be detachably coupled to the main frame 110 using threaded fasteners or latches. The slit valve 300 may separate the first space 104 and the second space 106 of the housing 100. The slit valve 300 may have a second internal space 302 that provides a passage between the first space 104 and the second space 106. The slit valve 300 may have a first opening 304 on a first side facing toward the cover frame 120 and a second opening 306 on a second side facing toward the main frame 110 (e.g., covering the aperture or opening of the main frame 110). The second internal space 302 may be in fluid communication with the first internal space 102 through the passage. For example, the second internal space 302 may be in fluid communication with the first space 104 in the main frame 110 through the second opening 306. The second internal space 302 may be in fluid communication with the second space 106 in the cover frame 120 through the first opening 304. The second internal space 302 and the first internal space 102 may provide a path through which the pendulum 200 rotates. The first opening 304 and the second opening 306 may have a sufficient size to allow the pendulum 200 to pass therethrough (e.g., larger than a profile of the pendulum 200). The pendulum 200 may, for example, move from the first space 104 to the second space 106 through the second opening 306, the second internal space 302, the first opening 304. Conversely, the pendulum 200 may move from the second space 106 to the first space 104 through the first opening 304, the second internal space 302, and the second openings 306. A vertical height of the second internal space 302 may be greater than a vertical height of the first opening 304 and a vertical height of second opening 306. The second space 106 of the cover frame 120, the second internal space 302 of the slit valve 300, the first space 104 of the main frame 110 and the exhaust line 3a, 3b may be sealed from the external environment.

The slit valve 300 may have a slit door 310. The slit door 310 may be movably disposed within the second internal space 302 of the slit valve 300. For example, the slit door 310 may be moved up and down in the second internal space 302. A size of the slit door 310 may be larger than a size of the first opening 304 and the second opening 306. The slit door 310 may open and close the second opening 306. For example, as shown in FIGS. 4 to 6, the slit door 310 may be moved up and down in a location between the first space 104 and the second space 106. The slit door 310 may move upward to close the second opening 306. When the slit door 310 closes the second opening 306, the first space 104 of the main frame 110 and the exhaust line 3a, 3b may be sealed from the second internal space 302. The first space 104 and the second space 106 may be separated by the slit door 310. For example, as shown in FIGS. 7 to 9, the slit door 310 may be configured to move downward from between the first space 104 and the second space 106. The slit door 310 may move downward to open the second opening 306. When the slit door 310 opens the second opening 306, the slit door 310 may be disposed in a lower portion of the second internal space 302, and the pendulum 200 may pass above the slit door 310. When the slit door 310 opens the second opening 306, the first space 104 may be opened (e.g., no longer obstructed by the slit door 310) such that the first space 104, the second internal space 302, and the second space 106 are connected with each other (e.g., are in fluid communication). Although FIGS. 3 to 9 show that the slit door 310 is provided in contact with the second opening 306 and opens and closes the second opening 306, the present invention is not limited thereto. According to other embodiments, the slit door 310 is provided in contact with the first opening 304, and may open and close the first opening 304. Alternatively, the slit door 310 may be provided in contact with both the first and second openings 304, 306, and may open and close the first and second openings 304, 306. Although FIGS. 3 to 9 show that the slit door 310 is moved in a vertical direction, the present invention is not limited thereto. According to other embodiments, various forms of the slit valve 300 may be provided, including the slit door 310 moving in a horizontal direction to open and close first or second openings 304, 306 or that rotate between an open and closed configuration.

Although FIGS. 3 to 9 show that the slit valve 300 is in a separate element from the main frame 110, the present invention is not limited thereto. According to other embodiments, the slit valve 300 may be provided as part of the main frame 110.

The pendulum valve apparatus 4 may further comprise a slit valve drive 320 for adjusting the movement of the slit door 310. The slit valve drive 320 may be coupled to the slit valve 300. The slit valve drive 320 may be located external to the slit valve 300. The slit valve drive 320 may have a valve shaft 330 connected to the slit door 310. The slit valve drive 320 may move the valve shaft 330 upward or downward to move the slit door 310, and the slit door 310 may block or open the first opening 304 or the second opening 306 by moving upward or downward in the second internal space 302 of the slit valve 300. The slit valve drive 320 may be a driving device such as an air cylinder, pneumatic cylinder, hydraulic cylinder, or linear actuator that provides a driving force for the moving upward/downward operation of the slit door 310.

According to embodiments of the present invention, when cover frame 120 and the pendulum 200 of the housing 100 are separated from the main frame 110, the first space 104 in the main frame 110 may be sealed by the slit valve 300. Therefore, it is possible to prevent the first space 104 in the main frame 110 from being contaminated by external air. In addition, the exhaust line 3, the vacuum pump 2, and the process chamber 1 connected to the first space 104 may be prevented from being contaminated by external air. This may increase the accuracy and yield of the process when performing the substrate processing process using the process chamber 1, the vacuum pump 2, and the exhaust line 3, and may prevent defects due to contamination of the substrate.

Furthermore, since the first space 104 is sealed by the slit valve 300, when the cover frame 120 and the pendulum 200 are separated, a treatment such as increasing the air pressure in the process chamber 1 to prevent contamination of the process chamber 1 may not be required.

In the following embodiments, components that are the same or substantially the same as those that were described previously in the embodiments of FIGS. 1 to 9 have the same reference numerals, and descriptions thereof may be omitted or briefly described for convenience of description. For example, the following description mainly describes the differences between the embodiments of FIGS. 1 to 9 and the following embodiments.

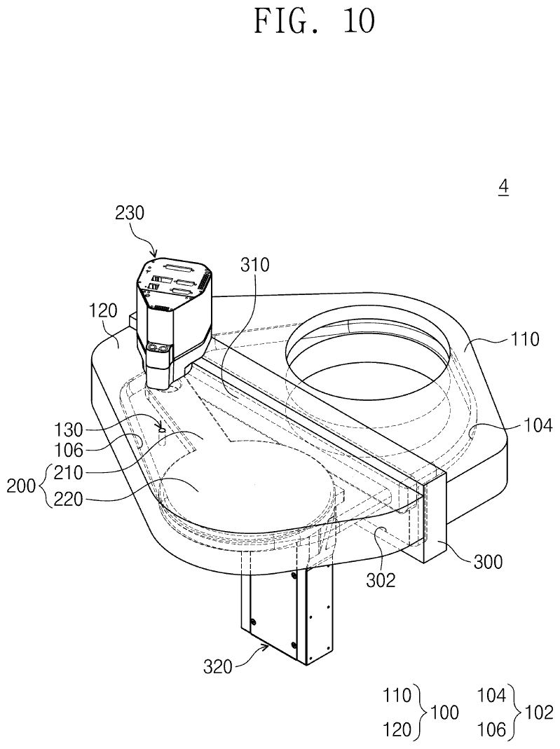

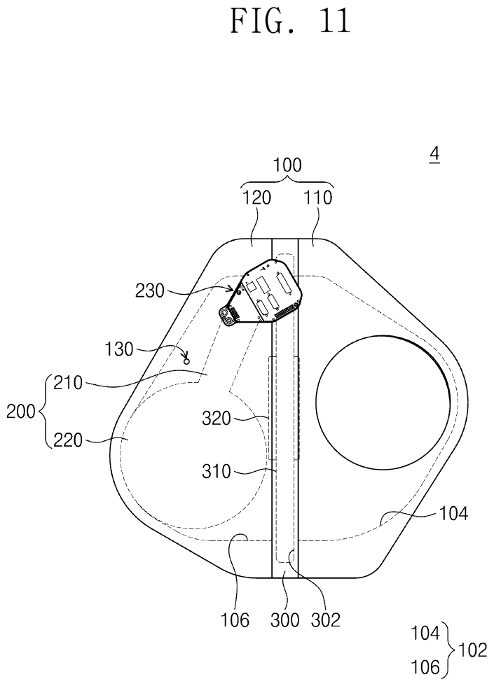

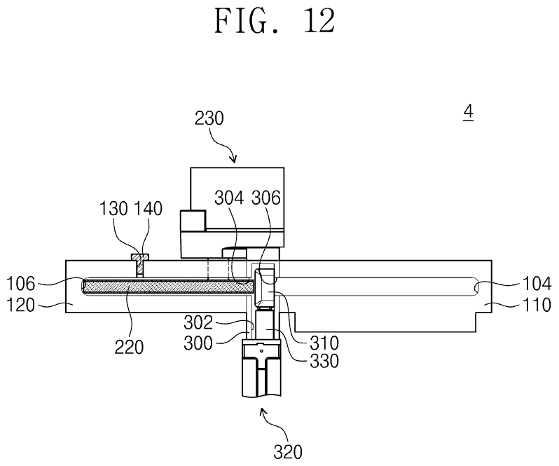

FIG. 10 is a perspective view illustrating a pendulum valve apparatus according to embodiments of the inventive concept, and shows the inside of the pendulum valve apparatus. FIG. 11 is a plan view of FIG. 10. FIG. 12 is a cross-sectional view of FIG. 10.

Referring to FIGS. 10 to 12, the pendulum valve apparatus 4 may include a housing 100 in which the first internal space 102 is provided, a pendulum 200 is provided in the first internal space 102 of the housing 100, and a slit valve 300 intersecting the first internal space 102 of the housing 100. The pendulum 200 may be rotated to open and close the gas flow passage of the exhaust line 3 as described previously.

The housing 100 may include a main frame 110 to which the exhaust line 3 is connected, and a cover frame 120 connected to the main frame 110.

The cover frame 120 may include a vent hole 130. The vent hole 130 may be connected with the second space 106 in the cover frame 120 through the cover frame 120. For example, the second space 106 may be connected to the outside of the cover frame 120 (e.g., externally).

The pendulum valve apparatus 4 may further include a vent hole plug 140 (e.g., a vent hole bung) that blocks the vent hole 130. The vent hole plug 140 may be inserted into the vent hole 130 to block the vent hole 130. The second space 106 of the cover frame 120, the second internal space 302 of the slit valve 300, the first space 104 of the main frame 110, and the exhaust line 3a, 3b may be sealed from the outside by the vent hole plug 140 (e.g., the vent hole plug 140 may prevent flow from inside the pendulum valve apparatus through the vent hole 130).

According to other embodiments, vent hole plug 140 may be omitted. For example, the pendulum valve apparatus 4 may further comprise a pressure regulator connected to the vent hole 130. The pressure regulator may regulate the pressure of the first internal space 102 in the housing 100. For example, the pressure regulator may regulate the pressure of the second space 106 in the cover frame 120 through the vent hole 130.

According to embodiments of the present invention, the second space 106 in the cover frame 120 may be connected externally through the vent hole 130. Accordingly, when the first space 104 and the second space 106 are separated from each other by the slit valve 300, the pressure in the second space 106 may be adjusted more easily during separating of the cover frame 120 from the main frame 110. Furthermore, the vent hole 130 may be closed using the vent hole plug 140, or the pressure in the second space 106 may be adjusted using the pressure regulator, so that the pressure in the housing 100 may be easily maintained or adjusted.

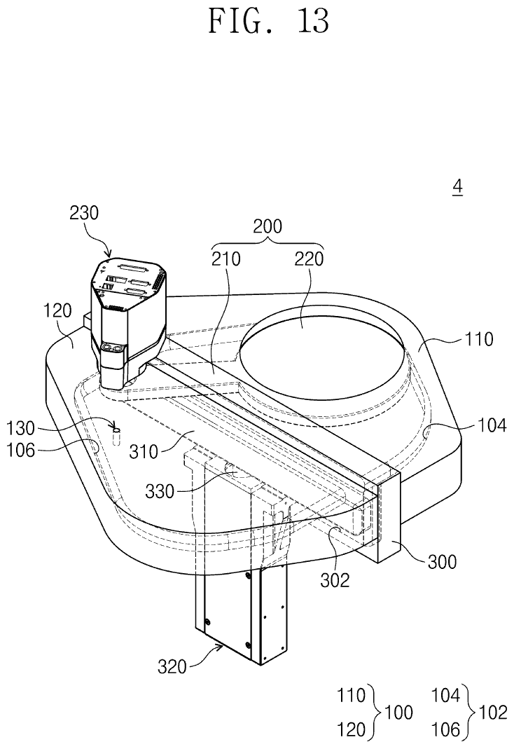

FIGS. 13 to 17 are perspective views for describing a processing method using a pendulum valve apparatus according to embodiments of the present invention.

Referring to FIGS. 3 and 13, a semiconductor manufacturing process may be performed in a substrate processing apparatus that includes a process chamber 1, a vacuum pump 2 for forming a vacuum pressure, an exhaust line 3 connecting the process chamber 1 and the vacuum pump 2, and a pendulum valve apparatus 4 provided to the exhaust line 3 to adjust a degree of vacuum. For example, the substrate processing process may be performed in the process chamber 1. During the substrate processing process, the vacuum pump 2 may provide a vacuum pressure to the process chamber 1 through the exhaust line 3 and the pendulum valve apparatus 4. Alternatively, during the substrate processing process, the vacuum pump 2 may provide a low-pressure or high-pressure to the process chamber 1 through the exhaust line 3 and the pendulum valve apparatus 4. For example, the pendulum 200 of the pendulum valve apparatus 4 may adjust the opening/closing state of the opening to which the exhaust line 3 is connected with the first space 104 in the main frame 110 of the housing 100. During the substrate processing process using the process chamber 1, various gases necessary for the process may flow through the exhaust line 3. The plate 220 of the pendulum 200 may become contaminated by the various gases flowing through the exhaust line 3. For example, the various gases may be adsorbed on the surface of the pendulum 200, or the gas may react with the surface of the pendulum 200. Accordingly, when the pendulum 200 becomes contaminated it may be necessary to separate the pendulum 200 from the housing for cleaning or maintenance of the pendulum 200.

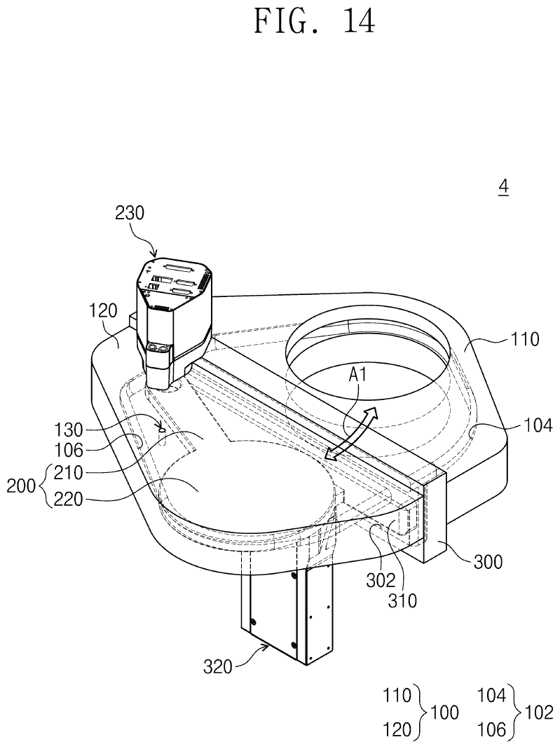

Referring to FIGS. 3 and 14, the plate 220 of the pendulum 200 may be moved from the first space 104 to the second space 106 along arrow A1 in FIG. 14. For example, the pendulum drive 230 may rotate the pendulum 200. The pendulum 200 may be received in the second space 106 of the cover frame 120. As the plate 220 of the pendulum 200 is moved into the second space 106, the exhaust line 3 may be opened. For example, the exhaust line 3 may be connected with the first space 104 of the main frame 110 and the second space 106 of the cover frame 120.

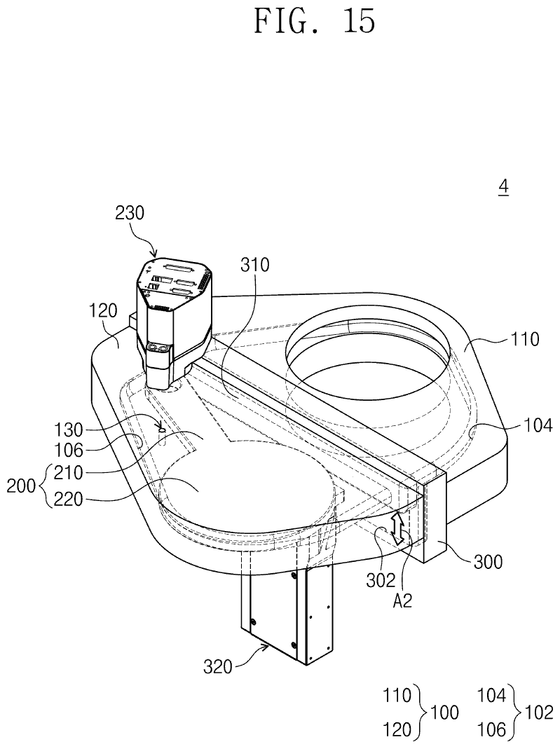

Referring to FIGS. 3 and 15, the slit valve 300 may seal the main frame 110 (e.g., seal the first space 104) once the plate 220 has moved into the second space 106. The slit door 310 of the slit valve 300 may move upward along the arrow A2 in FIG. 15 to close the second opening 306 (see FIG. 9). As shown in the embodiment of FIG. 9, the first space 104 of the main frame 110 connected with the second opening 306 may be sealed from an external space (e.g., sealed from the ambient environment) by the slit door 310. As a result of the first space 104 being sealed by the slit door 310, the first space 104 of the main frame 110, an interior of the exhaust line 3, and an interior of the process chamber 1 may be blocked from an external atmosphere and may have the same pressure as each other.

According to other embodiments, the slit door 310 of the slit valve 300 may move upward along arrow A2 in FIG. 15 to close the first opening 304 (see FIG. 9). Accordingly, the first opening 304, the second internal space 302 of the slit valve 300 and the first space 104 of the main frame 110 may be sealed from the external space by the slit door 310. As a result of the slit door 310 sealing the first opening 304, the second internal space 302 of the slit valve 300, the first space 104 of the main frame 110, the interior of the exhaust line 3, and the interior of the process chamber 1 may be blocked from the external atmosphere and may have the same pressure as each other.

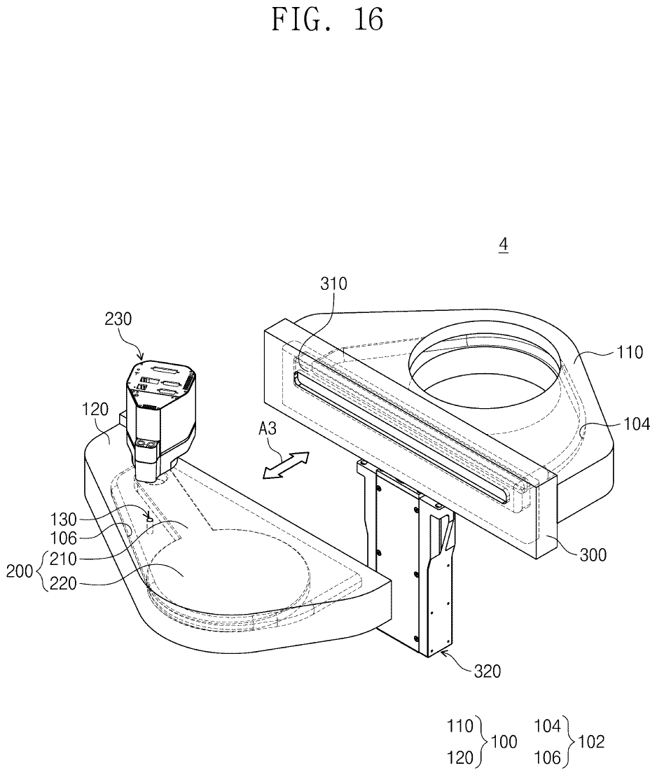

Referring to FIGS. 3 and 16, the cover frame 120 may be detached from the main frame 110. The cover frame 120 may be detached from the slit valve 300 along arrow A3 in FIG. 16. For example, the cover frame 120 may be detached from the slit valve 300 once the slit door 310 seals the first space 104 from the external environment.

In embodiments in which the cover frame 120 has the vent hole 130, the pressure of the second space 106 in the cover frame 120 may be regulated through a pressure regulator connected to the vent hole 130 or by removing the vent hole plug 140. Accordingly, a pressure difference between the second space 106 of the cover frame 120 and the external environment may be reduced, and the cover frame 120 may be more easily detached.

According to embodiments of the present invention, when the cover frame 120 is detached from the main frame 110, the first space 104 in the main frame 110 may remain sealed by the slit valve 300. Therefore, the first space 104 in the main frame 110, the exhaust line 3 connected to the first space 104, the vacuum pump 2, and the process chamber 1 may be prevented from being contaminated by external gas (e.g., ambient air).

Moreover, since the first space 104 is sealed by the slit valve 300, when the cover frame 120 and the pendulum 200 are separated, a treatment such as increasing the air pressure in the process chamber 1 to prevent contamination of the process chamber 1 may not be required. For example, through the use of the slit valve 300, no additional process may be needed when separating the pendulum valve apparatus, such as adjusting the pressure provided by the vacuum pump 2, adjusting the pressure in the process chamber 1, or cleaning the process chamber 1 and/or the exhaust line 3 which would otherwise be contaminated due to separation of the pendulum valve apparatus 4. Therefore, a processing method using the pendulum valve apparatus 4 with a simple process step may be provided.

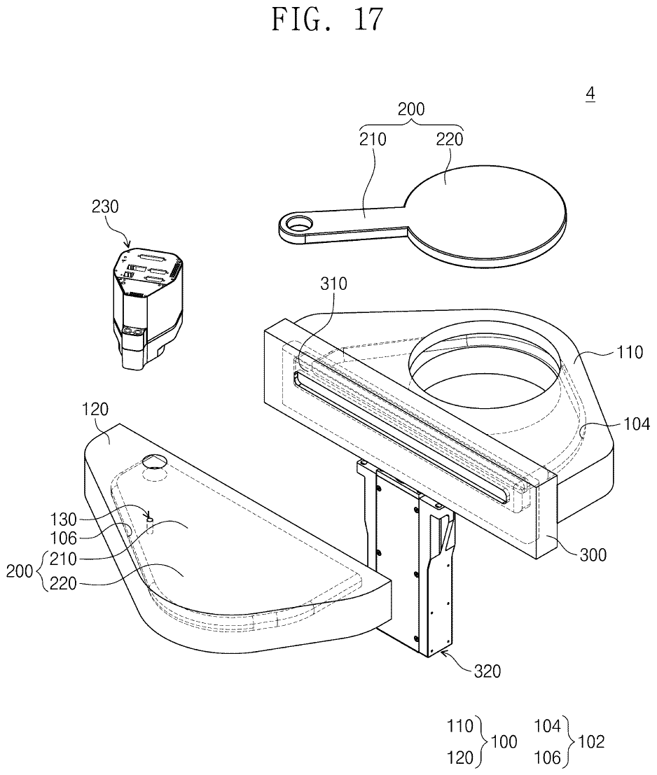

Referring to FIGS. 3 and 17, the pendulum 200 and the pendulum drive 230 may be detached from the cover frame 120. Processing such as cleaning or maintenance may be performed on the pendulum 200 and the pendulum drive 230. For example, with the slit door 310 sealing the first space and the cover frame 120 detached from the main frame 110, the pendulum 200 and pendulum drive 230 may be detached and cleaned.

After the processing (e.g., cleaning of the pendulum) is performed, the pendulum 200 and the pendulum drive 230 may be coupled to the cover frame 120.

Referring again to FIGS. 3 and 16, the cover frame 120 may be coupled to the main frame 110. The cover frame 120 may be coupled to the slit valve 300 along arrow A3 in FIG. 16.

In embodiments in which the cover frame 120 has the vent hole 130, the vent hole 130 may be closed with the vent hole plug 140. Alternatively, the pressure of the second space 106 in the cover frame 120 may be regulated through a pressure regulator connected to the vent hole 130. Accordingly, a pressure difference between the second space 106 of the cover frame 120 and the first space 104 of the main frame 110 may be reduced, and a problem caused by a pressure difference between the first space 104 and the second space 106 may be minimized.

Referring again to FIGS. 3 and 15, the slit valve 300 may open the main frame 110. The slit door 310 of the slit valve 300 may move downward along arrow A2 in FIG. 15 to open the second opening 306 (see FIG. 9). Accordingly, the first space 104 of the main frame 110 connected with the second opening 306 may be in fluid communication with the second internal space of the slit valve 300 and the second space 106 of the cover frame 120 connected with the first opening 304 (see FIG. 9).

Referring again to FIGS. 3 and 14, the plate 220 of the pendulum 200 may move from the second space 106 to the first space 104 along arrow A1 in FIG. 14. For example, the pendulum drive 230 may rotate the pendulum 200. The pendulum 200 may open and close the exhaust line 3 in the first space 104 of the cover frame 120 according to process conditions.

Even if the cover frame and the pendulum of the pendulum valve housing according to embodiments of the present invention are separated from the main frame, the first space in the main frame may be sealed by the slit valve. Therefore, it is possible to prevent the first space in the main frame from being contaminated by external air. It is also possible to prevent the exhaust line, the vacuum pump and the process chamber connected to the first space from being contaminated by external air. This may increase the accuracy and yield of the process when performing the substrate processing process using the process chamber, the vacuum pump, and the exhaust line, and may prevent defects due to contamination of the substrate.

Moreover, as the first space is sealed by the slit valve, upon separation of the cover frame and the pendulum, treatment such as increasing the air pressure in the process chamber to prevent contamination of the process chamber may not be necessary. That is, no additional process may be needed to adjust the pressure provided by the vacuum pump, to adjust the pressure in the process chamber, or to clean the process chamber or exhaust line that is contaminated due to separation of the pendulum valve apparatus. In other words, a processing method for a pendulum valve apparatus with a simple process step may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A pendulum valve apparatus comprising:
a housing including a main frame, a cover frame, and a vent passage in the main frame, the vent passage configured to connect to an exhaust line;
a pendulum provided in the housing, the pendulum configured to selectively seal the vent passage; and
a slit valve between the main frame and the cover frame of the housing,
wherein the main frame encloses a first space in the main frame and the cover frame encloses a second space in the cover frame, and
wherein the slit valve is configured to selectively open and close an aperture of the first space, the aperture of the first space being located between the first space and the second space.

2. The pendulum valve apparatus of claim 1, wherein the pendulum is rotatably coupled to the cover frame.

3. The pendulum valve apparatus of claim 1, further comprising a pendulum drive,
wherein the pendulum drive is configured to:
move the pendulum between a first position in the first space in which the pendulum seals the vent passage and a second position in the second space to open the vent passage.

4. The pendulum valve apparatus of claim 3, wherein the pendulum drive is coupled to the cover frame.

5. The pendulum valve apparatus of claim 1, wherein the slit valve comprises a passage between the first space and the second space, and
wherein the passage provides a movement path for the pendulum.

6. The pendulum valve apparatus of claim 5, wherein:
the slit valve comprises a slit valve door and a slit valve drive, and
the slit valve drive is configured to:
move the slit valve door between a first position in which the slit valve door obstructs the passage between the first space and the second space to seal the first space and a second position in which the slit valve door does not obstruct the passage.

7. The pendulum valve apparatus of claim 1, wherein the slit valve is disposed between the main frame and the cover frame, the slit valve is coupled to the main frame, and the cover frame is detachably coupled to the slit valve.

8. The pendulum valve apparatus of claim 7, wherein, the cover frame is configured to house the pendulum when the cover frame is detached from the slit valve, and
the slit valve is configured to seal the aperture of the first space with the cover frame removed from the slit valve.

9. The pendulum valve apparatus of claim 1, wherein the cover frame further includes a vent hole providing a fluid path through the cover frame into the second space.

10. The pendulum valve apparatus of claim 9, wherein the cover frame includes:
a vent hole plug configured to selectively open and close the vent hole; or
a pressure regulator connected to the vent hole and configured to regulate a pressure of the second space.

11. The pendulum valve apparatus of claim 1, wherein in a plan view taken perpendicular to a rotation axis of the pendulum, the second space in the cover frame has a larger area than that of the pendulum.

12. A substrate processing apparatus comprising:
a chamber having a substrate processing space disposed therein;
a pump configured to regulate a pressure inside the chamber;
an exhaust line connecting the chamber and the pump; and
a pendulum valve apparatus provided on the exhaust line,
wherein the pendulum valve apparatus comprises:
a housing enclosing a first space and a second space therein, and the exhaust line is connected to the first space;
a pendulum connected to the housing;
a pendulum drive connected to the pendulum in the second space of the housing and configured to provide a driving force to the pendulum to selectively move a portion of the pendulum between the first space and the second space; and
a slit valve coupled to the housing and configured to selectively seal an aperture of the first space, the slit valve being disposed between the first space and the second space.

13. The substrate processing apparatus of claim 12, wherein the housing comprises:
a main frame enclosing the first space; and
a cover frame enclosing the second space,
wherein the slit valve is coupled to the main frame and positioned between the main frame and the cover frame, and
wherein the cover frame is detachably coupled to the slit valve to be removable from the main frame.

14. The substrate processing apparatus of claim 12, wherein the slit valve is coupled to the housing and includes a slit door that is movable within the housing,
wherein the slit valve is moveable from a first configuration that seals the first space and a second configuration that opens a passage between the first space and the second space.

15. The substrate processing apparatus of claim 14, wherein, the pendulum drive is configured to move the portion of the pendulum when the slit valve opens the passage between the first space and the second space, the portion of the pendulum configured to move between the first space to close the exhaust line and the second space to open the exhaust line.

16. The substrate processing apparatus of claim 14, further comprising a slit valve drive configured to:
move the slit door between a first position that is between the first space and the second space to seal the first space and a second position that is not between the first space and the second space to open the passage between the first space and the second space.

17. The substrate processing apparatus of claim 12, wherein, when the slit valve seals the first space, the first space is in fluid communication with the pump and the chamber.

18. The substrate processing apparatus of claim 17, wherein, when the slit valve seals the first space, the substrate processing space of the chamber and the first space have same pressure.

19. A method of operating a pendulum valve apparatus that comprises a housing connected to an exhaust line connecting a chamber with a vacuum pump, the housing including a main frame providing a first space connected to the exhaust line and a cover frame providing a second space connected to the first space, a pendulum provided in the second space of the cover frame, and a slit valve connected to the main frame and connecting the second space to the first space, comprising:
moving a portion of the pendulum through the slit valve from the first space into the second space;
with the portion of the pendulum disposed in the second space, closing the slit valve to seal the first space from the second space;
separating the cover frame and the pendulum from the main frame with the slit valve closed and sealing the first space;
coupling the cover frame and the pendulum to the main frame with the slit valve closed and sealing the first space;
opening the slit valve to open a passage between the first space and the second space; and
moving the portion of the pendulum into the first space through the slit valve to seal the exhaust line.

20. The method of claim 19, wherein, when the slit valve is closed to seal the first space,
the first space of the housing, the chamber, and the vacuum pump are in fluid communication, and
the first space and a substrate processing space of the chamber have the same internal pressure.
